(19) United States
(12) Patent Application Publication
(10) Pub. No.: US 2014/0374705 A1
(43) Pub. Date: Dec. 25, 2014

(54) ORGANIC LIGHT-EMITTING DISPLAY DEVICE AND METHOD OF MANUFACTURING THE SAME

(71) Applicant: SAMSUNG DISPLAY CO., LTD., Yongin-City (KR)

(72) Inventors: Ha Jin Song, Hwaseong-si (KR); Ji Young Kwon, Uijeongbu-si (KR); Yi Seul Kim, Ansan-si (KR); Ji Myoung Ye, Sasang-gu (KR); Byeong Wook Yoo, Hwaseong-si (KR); Bum Suk Lee, Hwaseong-si (KR)

(73) Assignee: SAMSUNG DISPLAY CO., LTD., Yongin-City (KR)

(21) Appl. No.: 14/074,647

(22) Filed: Nov. 7, 2013

(30) Foreign Application Priority Data
Jun. 21, 2013 (KR) 10-2013-0071584

(51) Int. Cl. H01L 27/32; H01L 51/56

(52) U.S. Cl. CPC H01L 27/3244; H01L 51/56
USPC 257/40; 438/34

(57) ABSTRACT

Organic light-emitting display device and method of manufacturing the same are provided. Here, the organic light-emitting display device includes a substrate which has a first area and a second area, a first electrode which is on each of the first area and the second area of the substrate, a plurality of emitting layers on the first electrode and including a first emitting layer on the first area and a second emitting layer on the second area, a second electrode on the emitting layers, a capping layer on the second electrode, and a refractive pattern on the capping layer, wherein the refractive pattern is on at least one of the first area and the second area.

### CROSS-REFERENCE TO RELATED APPLICATION

This application claims priority to and the benefit of Korean Patent Application No. 10-2013-0071584, filed on Jun. 21, 2013 in the Korean Intellectual Property Office, the disclosure of which is incorporated herein by reference in its entirety.

### BACKGROUND

1. Field

The following description relates to an organic light-emitting display device and a method of manufacturing the same.

2. Description of the Related Art

Generally, an organic light-emitting display device includes an anode, a cathode, and organic layers interposed between the anode and the cathode. The organic layers include at least an emitting layer (EML) and may further include a hole injecting layer (HIL), a hole transport layer (HTL), an electron transport layer (ETL) and an electron injecting layer (EIL). In the organic light-emitting display device, holes and electrons generated by the anode and the cathode may combine in an organic layer, particularly, in the emitting layer to form excitons. When an energy level of the excitons changes from an excited state to a ground state, the emitting layer may emit light of a color corresponding to the changed energy level.

The organic layers of the organic light-emitting display device are vulnerable to external oxygen and moisture. Therefore, a capping layer (CPL) that can block external oxygen and moisture is required. The capping layer is disposed on the cathode and protects the organic layers of the organic light-emitting display device from external oxygen and moisture.

However, if the capping layer is formed as a single layer, it may only be able to protect the layers fully stacked thereunder.

Therefore, the capping layer may be formed as a multilayer. In addition, luminance and lateral visibility may be improved by varying a refractive index of each layer in the capping layer. That is, a low refractive layer may be disposed on the cathode, and a high refractive layer may be disposed on the low refractive layer, thereby improving the luminance and lateral visibility of light generated from an emitting layer.

However, even if the capping layer is formed as a multilayer, since the capping layer is formed on the whole surface of a substrate, it may be difficult to improve the luminance and lateral visibility of light emitted from the emitting layer according to the color of the light. That is, the emitting layer may emit red light, green light or blue light. Since the red light, the green light and the blue light have different characteristics, for example, different wavelengths, it is required to improve the luminance and lateral visibility of light emitted from the emitting layer according to the color of the light.

### SUMMARY

Aspects of embodiments of the present invention are directed toward an organic light-emitting display device which can improve the luminance and lateral visibility of light emitted from an emitting layer according to the color of the emitted light.

Aspects of embodiments of the present invention are also directed toward a method of manufacturing an organic light-emitting display device which can improve the luminance and lateral visibility of light emitted from an emitting layer according to the color of the light.

However, aspects of the present invention are not restricted to the one set forth herein. The above and other aspects of the present invention will become more apparent to one of ordinary skill in the art to which the present invention pertains by referencing the detailed description given below.

According to an embodiment of the present invention, an organic light-emitting display device includes: a substrate which has a first area and a second area; a first electrode on each of the first area and the second area of the substrate; a plurality of emitting layers on the first electrode and including a first emitting layer on the first area and a second emitting layer on the second area; a second electrode on the emitting layers; a capping layer on the second electrode; and a refractive pattern on the capping layer, wherein the refractive pattern is on at least one of the first area and the second area.

According to another embodiment of the present invention, an organic light-emitting display device includes: a substrate having a first area and a second area; a first electrode on each of the first area and the second area of the substrate; a plurality of emitting layers on the first electrode and including a first emitting layer on the first area and a second emitting layer on the second area; a second electrode on the emitting layers; a capping layer on the second electrode; and a refractive pattern on the capping layer, wherein the refractive pattern has a convex shape.

According to still another embodiment of the present invention, a method of manufacturing an organic light-emitting display device includes: forming a first electrode on each of a first area, a second area and a third area of a substrate; forming a first emitting layer, a second emitting layer and a third emitting layer on the first electrode on the first area, the first electrode on the second area and the first electrode on the third area, respectively; forming a second electrode on the first emitting layer, the second emitting layer and the third emitting layer; forming a capping layer on the second electrode; and forming a refractive pattern on at least one of the capping layer on the first area and the capping layer on the second area.

### BRIEF DESCRIPTION OF THE DRAWINGS

The above and other aspects and features of the present invention will become more apparent by describing in more detail example embodiments thereof with reference to the attached drawings, in which:

FIG. 1 is a cross-sectional view of an organic light-emitting display device according to an embodiment of the present invention;

FIGS. 2 through 6 are cross-sectional views illustrating a method of manufacturing the organic light-emitting display device of FIG. 1;

FIG. 7 is a cross-sectional view of an organic light-emitting display device according to another embodiment of the present invention;

FIGS. 8 through 10 are cross-sectional views illustrating a method of manufacturing the organic light-emitting display device of FIG. 7;

FIG. 11 is a cross-sectional view of an organic light-emitting display device according to another embodiment of the present invention;

FIGS. 12 through 17 are cross-sectional views illustrating a method of manufacturing the organic light-emitting display device of FIG. 11;

FIG. 18 is a cross-sectional view of an organic light-emitting display device according to another embodiment of the present invention; and

FIGS. 19 through 24 are cross-sectional views illustrating a method of manufacturing the organic light-emitting display device of FIG. 18.

### DETAILED DESCRIPTION

Enhancements and features of the present invention and methods of accomplishing the same may be understood more readily by reference to the following detailed description of example embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims, and equivalents thereof. Thus, in some embodiments, known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present invention refers to “one or more embodiments of the present invention.”

Spatially relative terms, such as “below,” “beneath,” “lower,” “above,” “upper,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings.

Embodiments described herein will be described referring to plan views and/or cross-sectional views by way of ideal schematic views of the invention. Accordingly, the example views may be modified depending on manufacturing technologies and/or tolerances. Therefore, the embodiments of the invention are not limited to those shown in the views, but include modifications in configuration formed on the basis of manufacturing processes. Therefore, regions shown in the drawings have schematic properties, and shapes of regions shown in the drawings are examples of specific shapes of regions of elements and do not limit aspects of the invention.

Hereinafter, embodiments of the present invention will be described with reference to the attached drawings.

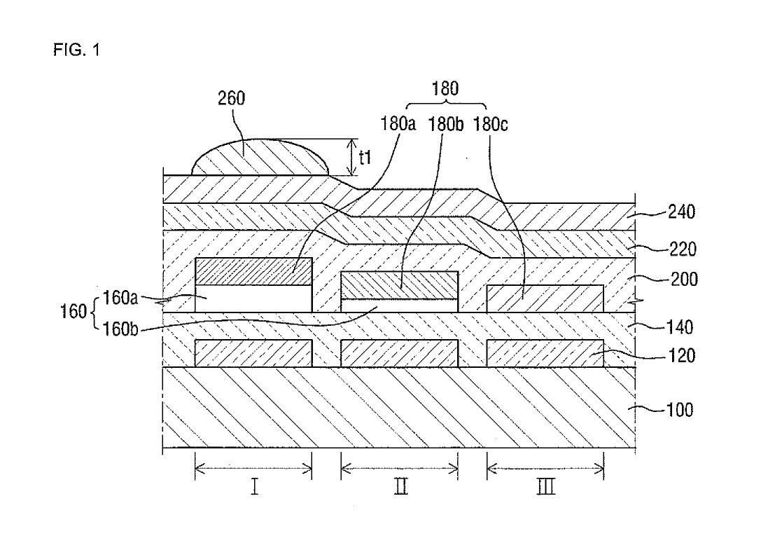

FIG. 1 is a cross-sectional view of an organic light-emitting display device according to an embodiment of the present invention. Referring to FIG. 1, the organic light-emitting display device according to the current embodiment may include a substrate 100, first electrodes (a plurality of first electrodes) 120, a first medium layer 140, a plurality of emitting layers 180, a plurality of resonance distance adjusting layers 160, a second medium layer 200, a second electrode 220, a capping layer 240, and a refractive pattern 260.

The substrate 100 may include an insulating substrate. The insulating substrate may be formed of a transparent glass material containing transparent SiO₂ as its main component. In some embodiments, the insulating substrate may be formed of an opaque material.

The substrate 100 may include a flexible substrate that can be deformed, for example, rolled, folded, bent, etc. The flexible substrate may be formed of a plastic material having superior thermal resistance and durability, such as polyethylene ether phthalate, polyethylene naphthalate, polycarbonate, polyarylate, polyetherimide, polyethersulfone, or polyimide. However, the present invention is not limited thereto, and various flexible materials can be used.

Although not shown in the drawing, the substrate 100 may further include other structures formed on the insulating substrate. Examples of the structures may include wirings, electrodes, and insulating layers. If the organic light-emitting display device according to the current embodiment is an active-matrix organic light-emitting display device, the substrate 100 may include a plurality of thin-film transistors (TFTs) formed on the insulating substrate. Each of the TFTs may include a gate electrode, a source electrode, and a drain electrode, and a semiconductor layer which is a channel region. The semiconductor layer may be formed of amorphous silicon, microcrystalline silicon, polycrystalline silicon, or monocrystalline silicon. In an alternative embodiment, the semiconductor layer may be formed of an oxide semiconductor. The drain electrodes of at least some of the TFTs may be electrically connected to the first electrodes 120.

The substrate 100 may have a plurality of areas. The areas of the substrate 100 may be separated from each other by a set or predetermined distance. The areas may be where a plurality of pixels are located. In an example embodiment, the areas may include a first area I, a second area II, and a third area III. The first area I, the second area II, and the third area III may emit red light, green light, and blue light, respectively. That is, the first area I, the second area II, and the third area III may be a red pixel area, a green pixel area, and a blue pixel area, respectively. In another example embodiment, the areas may additionally include a fourth area. The fourth area may emit white light.

The first electrodes 120 are formed on the substrate 100. Each of the first electrodes 120 may be located on each of the areas of the substrate 100, respectively. That is, each of the first electrodes 120 may respectively be formed in each of the pixel areas such that the first electrodes 120 are separated from each other. In an example embodiment, the first electrodes 120 may be disposed on all of the first area I, the second area II, and the third area III of the substrate 100. The first electrodes 120 may be formed on the substrate 100 to directly contact the substrate 100, or a material such as an insulating layer may be interposed between the first electrodes 120 and the substrate 100.

The first electrodes 120 may be anodes or cathodes. If the first electrodes 120 are anodes, the second electrode 220 may be a cathode. Thus, embodiments of the present invention will be described below based on this assumption. However, the first electrodes 120 may also be cathodes, and the second electrode 220 may also be an anode.

To be used as anodes, the first electrodes 120 may be formed of a conductive material with a high work function. If the organic light-emitting display device (OLED) is a bottom emission OLED, the first electrodes 120 may be formed of a material such as indium tin oxide (ITO), indium zinc oxide (IZO), zinc oxide (ZnO) or In₂O₃ or may be formed of a stacked layer (multiple layers stacked over one another) of these materials. If the organic light-emitting display device is a top emission OLED, the first electrodes 120 may further include a reflective layer formed of Ag, Mg, Al, Pt, Pd, Au, Ni, Nd, Ir, Cr, Li or Ca. The first electrodes 120 can be modified in various ways to have, for example, a structure composed of two or more layers formed using two or more different materials selected from the above materials.

Although not shown in FIG. 1, a pixel defining layer may be interposed between the first electrodes 120 of different pixels to divide the pixels. The pixel defining layer may be formed on the substrate 100 and include openings that expose regions of the substrate 100 on which the first electrodes 120 of the pixels are to be formed, respectively. The pixel defining layer may be formed of at least one organic material selected from benzocyclobutene (BCB), polyimide (PI), polyamaide (PA), acrylic resin and phenolic resin, or may be formed of an inorganic material such as silicon nitride.

The first medium layer 140 may be formed on the first electrodes 120. The first medium layer 140 may help the injection or transportation of electrons or holes between the first electrodes 120 and the second electrode 220. If the first electrodes 120 are anodes, the first medium layer 140 may be a layer related to the injection or transportation of holes.

The first medium layer 140 may be divided into a plurality of sections corresponding respectively to the pixels. Alternatively, the first medium layer 140 may be formed as a single piece over the whole surface of the substrate 110, as shown in FIG. 1. That is, the first medium layer 140 may be formed as a common layer regardless of the division between the pixels. In other words, the first medium layer 140 may be formed commonly to the areas of the substrate 100. In some embodiments, the first medium layer 140 may be omitted.

The first medium layer 140 may include a hole injecting layer and/or a hole transport layer. In an example embodiment, the first medium layer 140 may include the hole injecting layer or the hole transport layer alone. In another example embodiment, the first medium layer 140 may include a stack of the hole injecting layer and the hole transport layer.

The hole injecting layer may be disposed on the first electrodes 120. The material that forms the hole injecting layer may be selected from suitable hole injection materials including, but not limited to, a phthalocyanine compound such as copper phthalocyanine, a starburst amine derivative such as TCTA or m-MTDATA, and a conductive polymer such as polyaniline/dodecylbenzenesulfonic acid (Pani/DBSA), poly(3,4-ethylenedioxythiophene/poly(4-styrenesulfonate) (PEDOT/PSS), polyaniline/camphor sulfonic acid (Pani/CSA), or polyaniline/poly (4-styrene-sulfonate) (PANI/PSS).

The hole transport layer may be disposed on the hole injecting layer. The material that forms the hole transport layer may be selected from suitable hole transport materials including, but not limited to, 1,3,5-tricarbazolyl benzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)-silane, N,N′-bis(3-methylphenyl)-N,N′-diphenyl-[1,1-biphenyl]-4,4′-diamine(TPD), N,N′-di(naphtalene-1-yl)-N,N′-diphenyl benzidine (NPD), N,N′-diphenyl-N,N′-bis(1-naphtyl)-(1,1′-biphenyl)-4,4′-diamine (NPB), poly(9,9-dioctylfluorene-co-N-(4-butylphenyl)diphenylamine) (TFB), and poly(9,9-dioctylfluorene-co-bis-(4-butylphenyl-bis-N,N-phenyl-1,4-phenylenediamin (PFB).

The hole injecting layer or the hole transport layer may be formed using various methods including vacuum deposition, spin coating, casting, and/or LB methods. In one embodiment, the vacuum deposition method is used. When the hole injecting layer or the hole transport layer is formed by the vacuum deposition method, its deposition conditions may vary according to a compound used as the material that forms the hole injecting layer or the hole transport layer and the intended structure and thermal characteristics of the hole injecting layer or the hole transport layer. However, the deposition conditions of the hole injecting layer or the hole transport layer may generally include a deposition temperature ranging from 100 to 500° C., a vacuum level ranging from 10⁻⁸ to 10⁻³ torr, and a deposition rate ranging from 0.01 to 100 Å/sec.

The emitting layers 180 may be formed on the first medium layer 140. Each of the emitting layers 180 may emit light of a certain color. Specifically, holes and electrons generated by the first electrodes 120 and the second electrode 220 may combine in the emitting layers 180 to form excitons. When an energy level of the excitons changes from an excited state to a ground state, each of the emitting layers 180 may emit light of a color corresponding to the changed energy level. In an example embodiment, the emitting layers 180 may emit red light, green light, and blue light. In another example embodiment, the emitting layers 180 may emit white light in addition to the red light, the green light and the blue light.

The emitting layers 180 may include a first emitting layer 180a, a second emitting layer 180b, and a third emitting layer 180c. In an example embodiment, the first emitting layer 180a may emit red light, the second emitting layer 180b may emit green light, and the third emitting layer 180c may emit blue light. The present invention will be described below based on this assumption but is not limited thereto.

The first emitting layer 180a may be disposed on the first electrode 120 located on the first area I. Specifically, the first emitting layer 180a may be disposed on the first electrode 120 which is exposed by an opening of the pixel defining layer located on the first area I.

The first emitting layer 180a may be formed of a polymer material or a small molecule organic material which uniquely emits red light, or a mixture of the polymer material and the small molecule organic material. In some embodiments, the first emitting layer 180a may include a red host material and a red dopant material.

The red host material of the first emitting layer 180a may include, but not limited to, one or more materials selected from bis(2-(2-hydroxyphenyl)benzothiazolato)zinc (Zn(BTZ)2) and bis-(2-methyl-8-quinolinolate)-4-(phenylphenolate)aluminum. The red dopant material of the first emitting layer 180a may be, but is not limited to, PtOEP, Ir(piq)₃, Btp₂Ir(acac), DCJTB, etc.

The second emitting layer 180b may be disposed on the first electrode 120 located on the second area II. Specifically, the second emitting layer 180b may be disposed on the first electrode 120 which is exposed by an opening of the pixel defining layer located on the second area II.

The second emitting layer 180b may be formed of a polymer material or a small molecule organic material which uniquely emits green light, or a mixture of the polymer material and the small molecule organic material. In some embodiments, the second emitting layer 180b may include a green host material and a green dopant material.

The green host material of the second emitting layer 180b may include one or more materials selected from, but not limited to, an anthracene derivative and a carbazole compound. The anthracene derivative may be 9,10-(2-dinaphthyl) anthracene (ADN), and the carbazole compound may be 4,4′-(carbazole-9-yl)biphenyl (CBP). The green dopant material of the second emitting layer 180b may be, but is not limited to, Ir(ppy)₃ (ppy=phenylpyridine), Ir(ppy)₂(acac), Ir(mpyp)₃, or C545T.

The third emitting layer 180c may be disposed on the first electrode 120 located on the third area III. Specifically, the third emitting layer 180c may be disposed on the first electrode 120 which is exposed by an opening of the pixel defining layer located on the third area III.

The third emitting layer 180c may be formed of a polymer material or a small molecule organic material which uniquely emits blue light, or a mixture of the polymer material and the small molecule organic material. In some embodiments, the third emitting layer 180c may include a blue host material and a blue dopant material.

The blue host material of the third emitting layer 180c may include one or more materials selected from, but not limited to, an anthracene derivative and a carbazole compound. The anthracene derivative may be 9,10-(2-dinaphthyl) anthracene (ADN), and the carbazole compound may be 4,4′-(carbazole-9-yl)biphenyl (CBP). The blue dopant material of the third emitting layer 180c may be, but is not limited to, F₂Irpic, (F₂ppy)₂Ir(tmd), Ir(dfppz)₃, ter-fluorene, etc.

The resonance distance adjusting layers 160 may be interposed between the first medium layer 140 and the emitting layers 180. Specifically, the resonance distance adjusting layers 160 may be interposed between the first medium layer 140 and the first emitting layer 180a and between the first medium layer 140 and the second emitting layer 180b. The resonance distance adjusting layers 160 may control the resonance cycle of light emitted from the emitting layers 180. In order to increase color purity, luminous efficiency, etc. of light emitted from the emitting layers 180, each of the resonance distance adjusting layers 160 may have a set or predetermined thickness. The resonance distance adjusting layers 160 may be formed of the same material as the hole transport layer.

The resonance distance adjusting layers 160 may include a first resonance distance adjusting layer 160a and a second resonance distance adjusting layer 160b.

The first resonance distance adjusting layer 160a may be disposed on the first area I and between the first medium layer 140a and the first emitting layer 180a. Specifically, the first resonance distance adjusting layer 160a may exist only on the first area I. That is, the first resonance distance adjusting layer 160a may not exist on the second area II and the third area III.

The first resonance distance adjusting layer 160a may be formed to a set or predetermined thickness in order to control the resonance cycle of light emitted from the first emitting layer 180a. The thickness of the first resonance distance adjusting layer 160a may be set to a set or predetermined thickness (distance) in order to increase the luminous efficiency, color purity, etc. of light emitted from the first emitting layer 180a. In an example embodiment, the first resonance distance adjusting layer 160a may be thicker than the second resonance distance adjusting layer 160b. The material that forms the first resonance distance adjusting layer 160a may be, but is not limited to, identical to the material that forms the hole transport layer. In an example embodiment, the first resonance distance adjusting layer 160a may include at least one material selected from silicon nitride (SiNₓ), silicon oxide (SiO₂), and silicon oxynitride (SiOₓN_{y}).

The second resonance distance adjusting layer 160b may be disposed on the second area II and between the first medium layer 140 and the second emitting layer 180b. Specifically, the second resonance distance adjusting layer 160b may exist only on the second area II. That is, the second resonance distance adjusting layer 160b may not exist on the first area I and the third area III.

The second resonance distance adjusting layer 160b may be formed to a set or predetermined thickness in order to control the resonance cycle of light emitted from the second emitting layer 180b. The thickness of the second resonance distance adjusting layer 160b may be set to a set or predetermined thickness in order to increase the luminous efficiency, color purity, etc. of light emitted from the second emitting layer 180b. The material that forms the second resonance distance adjusting layer 160b may be, for example, identical to the material that forms the hole transport layer. In an example embodiment, the second resonance distance adjusting layer 160b may include at least one material selected from silicon nitride (SiNₓ), silicon oxide (SiO₂), and silicon oxynitride (SiOₓN_{y}).

The second medium layer 200 may be formed on the emitting layers 180. The second medium layer 200 may help the injection or transportation of electrons or holes between the first electrodes 120 and the second electrode 220. If the second electrode 220 is a cathode, the second medium layer 200 may be a layer related to the injection or transportation of electrons.

The second medium layer 200 may be divided into a plurality of sections corresponding respectively to the pixels. Alternatively, the second medium layer 200 may be formed as a single piece over the whole surface of the substrate 100, as shown in FIG. 1. That is, the second medium layer 200 may be formed as a common layer regardless of the division between the pixels. In other words, the second medium layer 200 may be formed commonly to the areas of the substrate 100. In some embodiments, the second medium layer 200 may be omitted.

The second medium layer 200 may include the electron transport layer and/or an electron injecting layer. In an example embodiment, the second medium layer 200 may include the electron transport layer or the electron injecting layer alone. In another example embodiment, the second medium layer 200 may include a stack of the electron transport layer and the electron injecting layer.

The electron transport layer may be disposed on the emitting layers 180. The material that forms the electron transport layer may be a suitable material that can stably transport electrons injected from an electron injection electrode (cathode). The material may be a known suitable material such as a quinoline derivative, in particular, but not limited to, tris(8-quinolinorate)aluminum (Alq₃), 3-(4-biphenylyl)-4-phenyl-5-(4-tert-butyl phenyl)-1,2,4-triazole (TAZ), BAlq, etc.

The electron injecting layer may be disposed on the electron transport layer. The electron injecting layer may be formed of a known suitable material such as, but not limited to, LiF, NaCl, CsF, Li₂O, BaO, etc.

The electron transport layer or the electron injecting layer may be formed using various methods including vacuum deposition and spin coating. When the electron transport layer or the electron injecting layer is formed using vacuum deposition or spin coating, the deposition or coating conditions may vary according to a compound used but are generally almost the same as those for the formation of the hole injecting layer.

The second electrode 220 may be formed on the second medium layer 200. The second electrode 220 used as a cathode may be formed of a conductive material with a low work function. The second electrode 220 may be formed of Ag, Mg, Al, Pt, Pd, Au, Ni, Nd, Ir, Cr, Li or Ca. If the organic light-emitting display device is a bottom emission OLED, the second electrode 220 may include a reflective layer. If the organic light-emitting display device is a top emission OLED, the second electrode 220 may be formed as a semi-transmissive layer.

The capping layer 240 may be disposed on the second electrode 220. The capping layer 240 may protect layers stacked thereunder and help light generated by the emitting layers 180 to be efficiently emitted toward the outside of the organic light-emitting display device.

The capping layer 240 may have a refractive index of higher than 1.3 to lower than 1.7. In addition, the refractive index of the capping layer 240 may be lower than a refractive index of the refractive pattern 260 which will be described later.

The capping layer 240 may be formed of one or more of an inorganic material and an organic material. That is, the capping layer 240 may be formed as an inorganic layer or an organic layer or may be formed as an organic layer containing inorganic particles.

Examples of the inorganic material that can be used in the capping layer 240 may include silicon oxide and magnesium fluoride.

The organic material that can be used in the capping layer 240 may be a polymer. Examples of the organic material that can be used in the capping layer 240 may include acrylic, polyimide, polyamide, and tris(8-hydroxyquinolinato)aluminum (Alq₃).

The materials that can be used in the capping layer 240 are not limited to the above example materials. That is, the capping layer 240 can be formed of various suitable materials known to those of ordinary skill in the art to which the present invention pertains.

The refractive pattern 260 may be disposed on the capping layer 240. The refractive pattern 260 may protect layers stacked thereunder and help light generated by the emitting layers 180 to be efficiently emitted toward the outside of the organic light-emitting display device.

The refractive pattern 260 may be disposed on at least one of the first area I and the second area II. In the example embodiment of FIG. 1, the refractive pattern 260 is disposed only on the first area I. However, the present invention is not limited thereto, and the refractive pattern 260 may also be disposed only on the second area II or on both the first area I and the second area II. In addition, the refractive pattern 260 may not be disposed on the third area III. However, the present invention is not limited thereto. If the refractive pattern 260 is disposed on the third area III, it may be thinner than the refractive pattern 260 disposed on the first area I and the refractive pattern 260 disposed on the second area II.

The refractive pattern 260 may have a refractive index of higher than 1.7 to lower than 2.7. The refractive index of the refractive pattern 260 may be higher than the refractive index of the capping layer 240.

The refractive pattern 260 may be formed of one or more of an inorganic material and an organic material. That is, the refractive pattern 260 may be formed as an inorganic layer or an organic layer or may be formed as an organic layer containing inorganic particles.

Examples of the inorganic material that can be used in the refractive pattern 260 may include zinc oxide, titanium oxide, zirconium oxide, silicon nitride, niobium oxide, tantalum oxide, tin oxide, nickel oxide, indium nitride, and gallium nitride.

The organic material that can be used in the refractive pattern 260 is a polymer such as acrylic, polyimide, polyamide, etc. In particular, the organic material that can be used in the refractive pattern 260 may include poly(3,4-ethylenedioxythiophene (PEDOT), 4,4′-bis[N-(3-methylphenyl)-N-phenylamino]biphenyl (TPD), 4,4′,4″-tris[(3-methylphenyl)phenylamino]triphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′-bis[N,N-bis(3-methylphenyl)-amino]-diphenylmethane (BPPM), 4,4′-dicarbazolyl-1,1′-biphenyl (CBP), 4,4′,4″-tris(N-carbazol)triphenylamine (TCTA), 2,2′,2″-(1,3,5-benzentolyl)tris-[1-phenyl-1H-benzoimidazol] (TPBI), and 3-(4-biphenyl)-4-phenyl-5-t-butylphenyl-1,2,4-triazole (TAZ).

The materials that can be used in the refractive pattern 260 are not limited to the above example materials. That is, the refractive pattern 260 can be formed of various suitable materials known to those of ordinary skill in the art to which the present invention pertains.

The refractive pattern 260 may have a convex shape. In an example embodiment, the refractive pattern 260 may be shaped like a convex lens. However, the present invention is not limited thereto, and the refractive pattern 260 may have various shapes including a regular hexahedron.

A thickness t1 of the refractive pattern 260 may be adjusted appropriately so as to enable the refractive pattern 260 to perform the function of protecting the layers stacked thereunder and perform the efficient light emission function.

Although not shown in FIG. 1, a transparent, insulating encapsulation substrate formed of glass, quartz, ceramic, or plastic may be disposed on the refractive pattern 260. The encapsulation substrate may be sealed with a sealant to protect the emitting layers 180. In addition, an air layer or filler may be disposed in a space between the encapsulation substrate and the refractive pattern 260.

The organic light-emitting display device according to the current embodiment can improve the luminance and lateral visibility of light emitted from each of the emitting layers 180 according to the color of the light. Specifically, the first emitting layer 180a, the second emitting layer 180b, and the third emitting layer 180c may emit red light, green light and blue light, respectively. The red light, the green light and the blue light may have different wavelengths. That is, from among the red light, the green light and the blue light, the red light may have a longest wavelength, and the blue light may have a shortest wavelength. Since light having a long wavelength exhibits excellent straightness, the red light exhibits best straightness, and the blue light exhibits worst straightness. That is, the red light having excellent straightness is not refracted much even when it passes through a medium having a certain refractive index. In other words, when the red light passes through a medium having a certain refractive index, a difference between an incidence angle of the red light and a refraction angle of the red light is not large. However, the blue light having poor straightness is refracted much when it passes through a medium having a certain refractive index. That is, when the blue light passes through a medium having a certain refractive index, a difference between an incidence angle of the blue light and a refraction angle of the blue light is large.

Such differences in characteristics may cause the lateral visibility of light of various colors emitted from the emitting layers 180 to differ from each other. Specifically, when the red light emitted from the first emitting layer 180a passes through the capping layer 240 having a certain refractive index, it is not refracted much due to its excellent straightness. Therefore, the lateral visibility of the red light is lower than the lateral visibility of light of other colors. On the other hand, the green light emitted from the second emitting layer 180b and the blue light emitted from the third emitting layer 180c have poorer straightness than the red light. Therefore, the lateral visibility of the green light and the lateral visibility of the blue light may be higher than that of the red light.

If light of various colors emitted from the emitting layers 180 have different levels of visibility as described above, color mixing and discoloration may occur when the organic light-emitting display device is viewed from the side.

In this regard, the organic light-emitting display device according to the current embodiment may be a top emission organic light-emitting display device, and the refractive pattern 260 may be placed on the first area I, on which the first emitting layer 180a for emitting red light is disposed, in order to increase the lateral visibility of the red light. That is, the refractive pattern 260 having a higher refractive index than the capping layer 240 may laterally refract the red light emitted from the first emitting layer 180a, thereby increasing the lateral visibility of the red light.

In addition, part of the red light emitted from the first emitting layer 180a may be reflected at an interface between the capping layer 240 and the refractive pattern 260. Accordingly, the resonance distance of the red light may be adjusted. That is, the interface between the capping layer 240 and the refractive pattern 260 may perform substantially the same function as the first resonance distance adjusting layer 160a. In some embodiments, the resonance distance of the red light may be adjusted using only the interface between the capping layer 240 and the refractive pattern 260, and the first resonance distance adjusting layer 160a may be omitted.

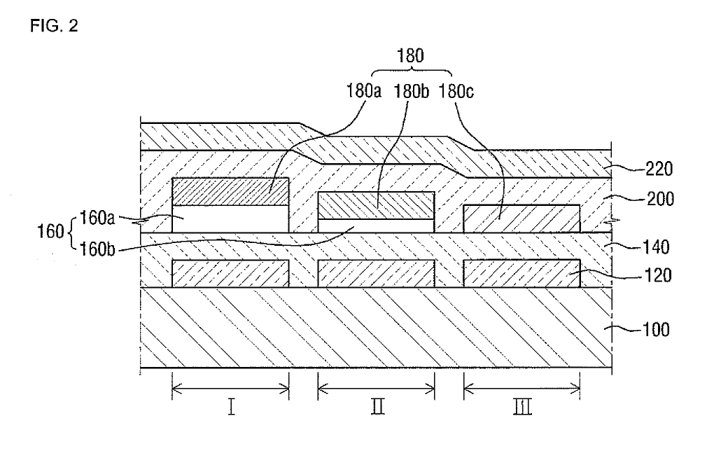

A method of manufacturing an organic light-emitting display device according to an embodiment of the present invention will now be described with reference to FIGS. 2 through 6. FIGS. 2 through 6 are cross-sectional views illustrating a method of manufacturing the organic light-emitting display device of FIG. 1. For simplicity, elements substantially identical to those of FIG. 1 are indicated by like reference numerals, and thus a redundant description thereof will be omitted.

Referring to FIG. 2, a stacked structure of a substrate 100, first electrodes (a plurality of first electrodes) 120, a first medium layer 140, a plurality of resonance distance adjusting layers 160, a plurality of emitting layers 180, a second medium layer 200, and a second electrode 220 may be prepared. Specifically, the first electrodes 120 may respectively be formed on a first area I, a second area II and a third area III of the substrate 100, and the first medium layer 140 may be formed on the first electrodes 120. Then, the resonance distance adjusting layers 160 and the emitting layers 180 may be formed on the first medium layer 140. Specifically, a first resonance distance adjusting layer 160a and a second resonance distance adjusting layer 160b may be formed on the first medium layer 140 disposed on the first area I and the first medium layer 140 disposed on the second area II, respectively. A first emitting layer 180a, a second emitting layer 180b and a third emitting layer 180c may be formed on the first resonance distance adjusting layer 160a disposed on the first area I, the second resonance distance adjusting layer 160b disposed on the second area II, and the first medium layer 140 disposed on the third area III, respectively. The second medium layer 200 may be formed on the emitting layers 180, and the second electrode 220 may be formed on the second medium layer 200.

The substrate 100, the first electrodes 120, the first medium layer 140, the resonance distance adjusting layers 160, the emitting layers 180, the second medium layer 200 and the second electrode 220 may be formed by a general deposition process or a general solution process.

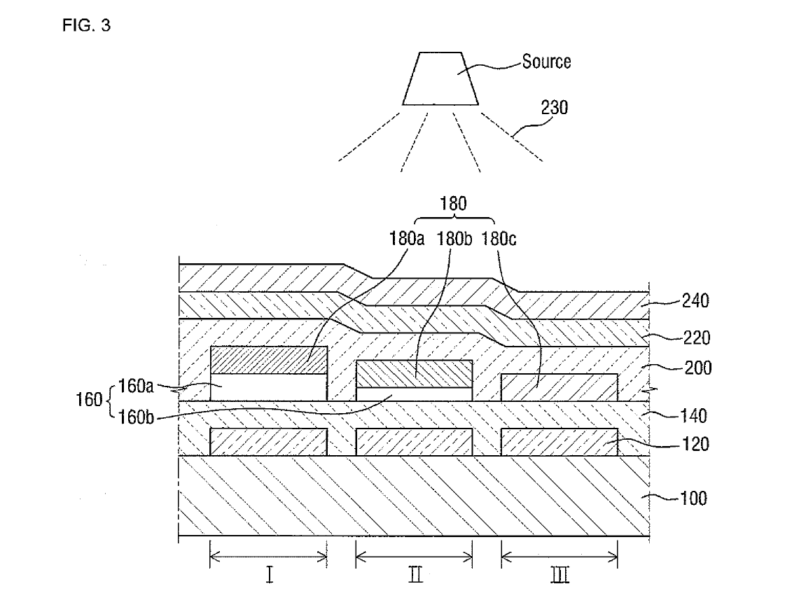

Referring to FIG. 3, a capping layer 240 may be formed on the second electrode 220 of the stacked structure. In one embodiment, a small molecule material 230 evaporating from a deposition source is deposited on the second electrode 220, thereby forming the capping layer 240. The capping layer 240 may be formed on the whole surface of the substrate 100. A surface of the capping layer 240 may be hydrophobic.

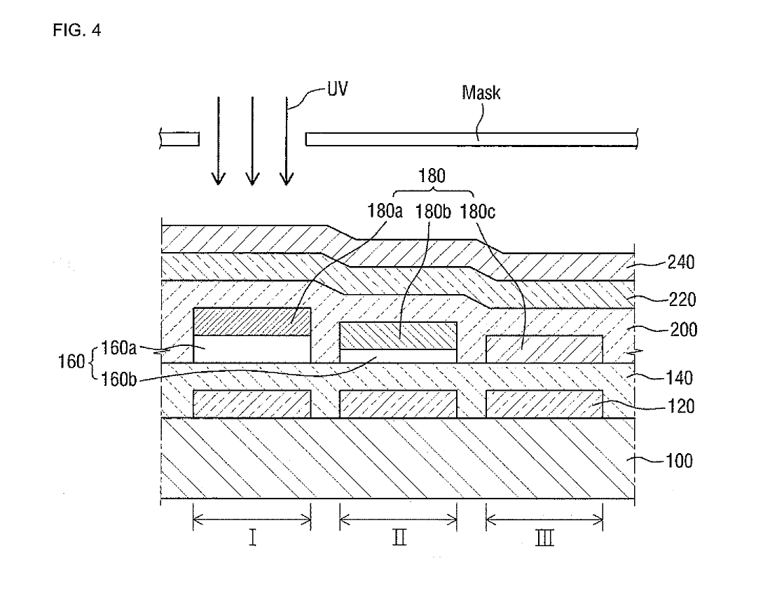

Referring to FIG. 4, only the capping layer 240 disposed on the first area I may be irradiated with light. Here, a mask may be placed such that an opening of the mask corresponds to the first area I, and light may be irradiated to the surface of the capping layer 240 disposed on the first area I through the opening. The irradiated light may be ultraviolet light but is not limited thereto. The irradiated light may include all light beams having higher energy than the ultraviolet light.

In one embodiment, when only the capping layer 240 disposed on the first area I is irradiated with light as described above, the surface of the capping layer 240 disposed on the first area I changes from hydrophobic to hydrophilic.

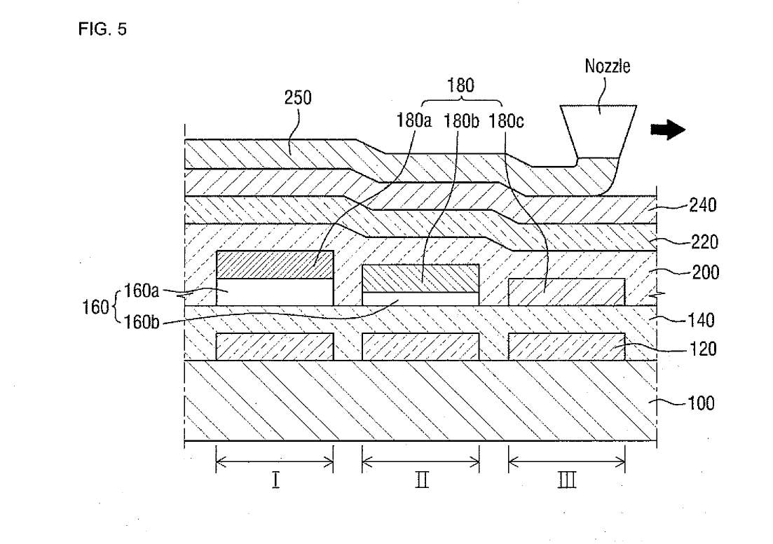

Referring to FIG. 5, in one embodiment, a polymer solution 250 is spread over the whole surface of the capping layer 240. The polymer solution 250 may be spread over the whole surface of the capping layer 240 using a nozzle. However, the present invention is not limited thereto, and various processes can be used. In an example, the surface of the capping layer 240 may be dipped into the polymer solution 250. In another example, the polymer solution 250 may be spin-coated or roll-printed on the capping layer 240. In another example, the polymer solution 250 may be screen-printed on the capping layer 240.

The polymer solution 250 may be spread over the whole surface of the capping layer 240 in a nitrogen gas environment, so that the spreading process can be performed in a stable manner.

If the polymer solution 250 is spread over the whole surface of the capping layer 240 as described above, the hydrophilic polymer solution 250 may agglomerate on the surface of the capping layer 240 which has become hydrophilic. That is, the polymer solution 250 may agglomerate only on the surface of the capping layer 240 which is disposed on the first area I and may not agglomerate on the surface of the capping layer 240 which is disposed on the area excluding the first area I.

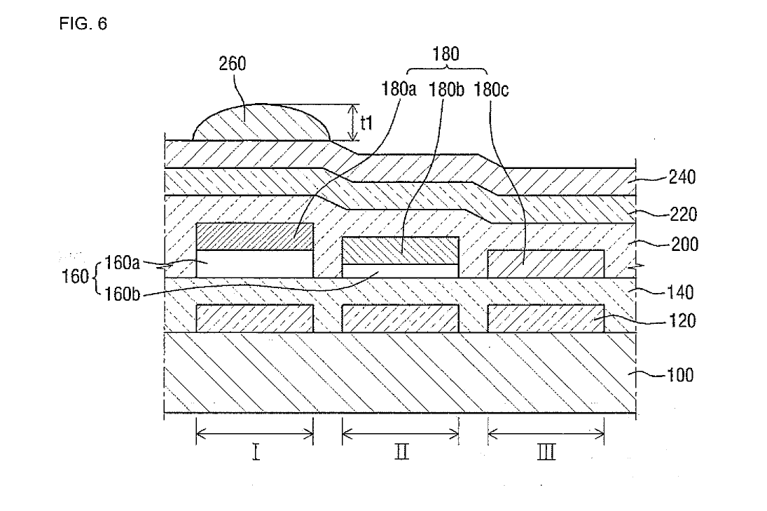

Referring to FIG. 6, a refractive pattern 260 may be formed by removing the polymer solution 250 disposed on the area excluding the first area I and evaporating a solvent of the polymer solution 250 disposed on the first area I. Here, the refractive pattern 260 may be shaped like a convex lens due to surface tension of the polymer solution 250.

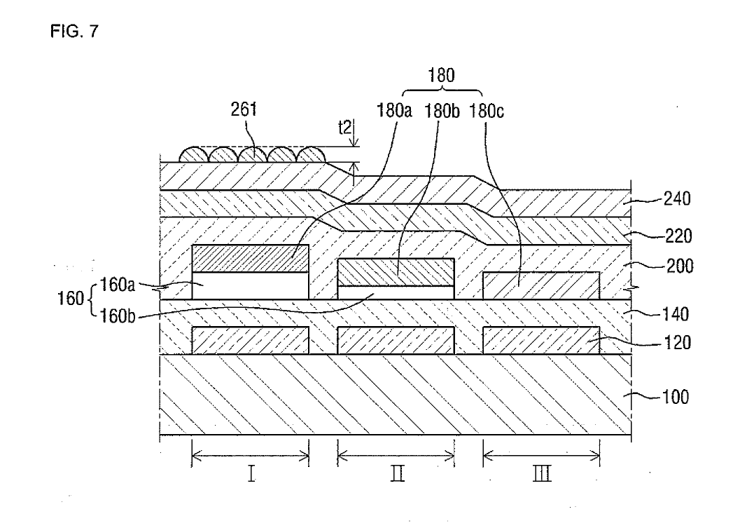

An organic light-emitting display device according to another embodiment of the present invention will now be described with reference to FIG. 7. FIG. 7 is a cross-sectional view of an organic light-emitting display device according to another embodiment of the present invention. For simplicity, elements substantially identical to those of FIG. 1 are indicated by like reference numerals, and thus a redundant description thereof will be omitted.

Referring to FIG. 7, in one embodiment, a refractive pattern 261 on a capping layer 240 disposed on a first area I includes a plurality of convex portions. Specifically, a thickness t2 of the refractive pattern 261 according to the current embodiment is smaller than the thickness t1 of the refractive pattern 260 according to the previous embodiment. However, the refractive pattern 261 according to the current embodiment can further increase the lateral visibility of red light by including the plurality of convex portions. That is, increasing the curvature of the refractive pattern 261 may be more effective in increasing the lateral visibility of the red light than increasing the thickness of the refractive pattern 261.

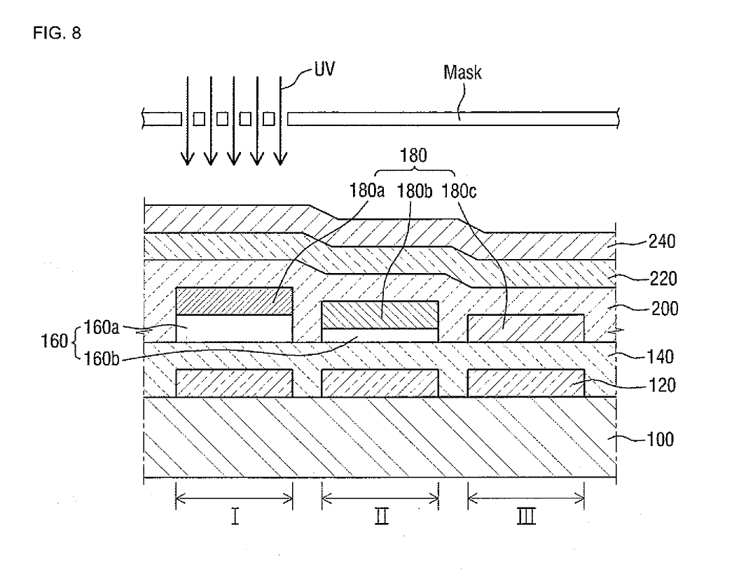

A method of manufacturing an organic light-emitting display device according to another embodiment of the present invention will now be described with reference to FIGS. 8 through 10. FIGS. 8 through 10 are cross-sectional views illustrating a method of manufacturing the organic light-emitting display device of FIG. 7. For simplicity, elements substantially identical to those of FIG. 7 are indicated by like reference numerals, and thus a redundant description thereof will not be provided again.

Referring to FIG. 8, a stacked structure prepared by the processes of FIGS. 2 and 3 may be selectively irradiated with light. Here, a mask different from the mask of FIG. 4 may be used. Specifically, a mask used in the current embodiment includes a plurality of openings. That is, the mask used in the current embodiment may be a slit mask including a plurality of slits as the openings.

The openings of the mask may be placed over a first area I, and light may be irradiated onto a capping layer 240 through the openings. In one embodiment, this process causes a surface of the capping layer 240 disposed on the first area I to have hydrophobic and hydrophilic portions arranged alternately.

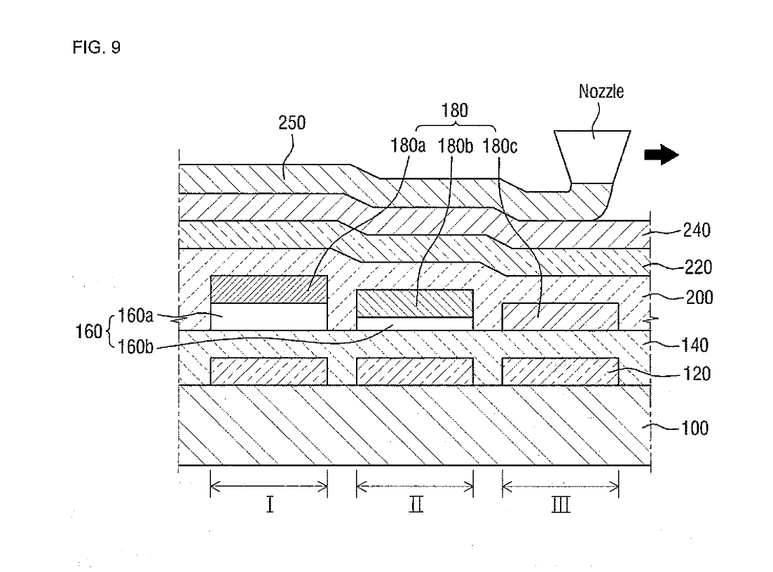

Referring to FIG. 9, a polymer solution 250 may be spread over the whole surface of the capping layer 240 as in the process of FIG. 5. If the polymer solution 250 is spread as described above, it may agglomerate only on the hydrophilic portions of the surface of the capping layer 240 disposed on the first area I.

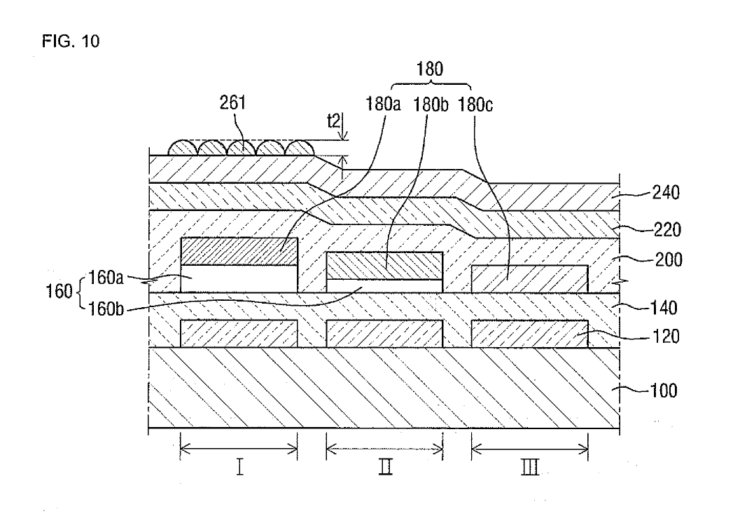

Referring to FIG. 10, the polymer solution 250 existing on the hydrophobic portions of the surface of the capping layer 240 may be removed, and the polymer solution 250 existing on the hydrophilic portions of the surface of the capping layer 240 may be left unremoved. Then, a solvent of the remaining polymer solution 250 may be evaporated to form a refractive pattern 261 including a plurality of convex portions.

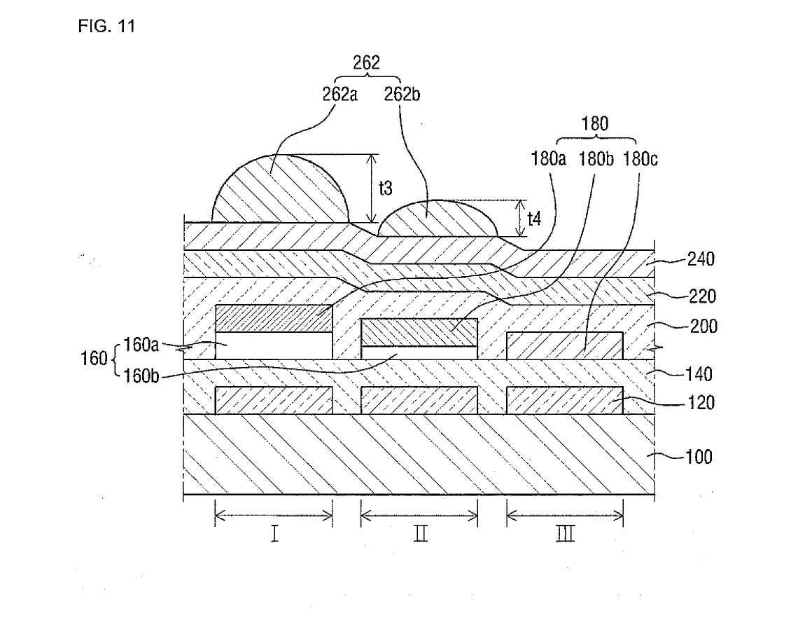

An organic light-emitting display device according to another embodiment of the present invention will now be described with reference to FIG. 11. FIG. 11 is a cross-sectional view of an organic light-emitting display device according to another embodiment of the present invention. For simplicity, elements substantially identical to those of FIG. 1 are indicated by like reference numerals, and thus a redundant description thereof will not be provided again.

Referring to FIG. 11, refractive patterns 262 of the organic light-emitting display device according to the current embodiment of the present invention include a first refractive pattern 262a and a second refractive pattern 262b.

The first refractive pattern 262a may be disposed on a capping layer 240 located on a first area I. The second refractive pattern 262b may be disposed on the capping layer 240 located on a second area II. In an example embodiment, a thickness t3 of the first refractive pattern 262a and a thickness t4 of the second refractive pattern 262b are different from each other. Specifically, the thickness t3 of the first refractive pattern 262a may be greater than the thickness t4 of the second refractive pattern 262b. In another example embodiment, a refractive index of the first refractive pattern 262a and a refractive index of the second refractive pattern 262b are different from each other. Specifically, the refractive index of the first refractive pattern 262a may be higher than the refractive index of the second refractive pattern 262b.

In the organic light-emitting display device according to the current embodiment, the lateral visibility levels of red light, green light and blue light can be adjusted to be equal by improving the lateral visibility of the red light the most and the lateral visibility of the green light the second most.

In addition, an interface between the capping layer 240 and the first refractive pattern 262a adjusts the resonance distance of the red light, and an interface between the capping layer 240 and the second refractive pattern 262b adjusts the resonance distance of the green light. This can improve the luminance of light generated from each of a first emitting layer 180a and a second emitting layer 180b. Furthermore, a second resonance distance adjusting layer 160b as well as a first resonance distance adjusting layer 160a can be omitted.

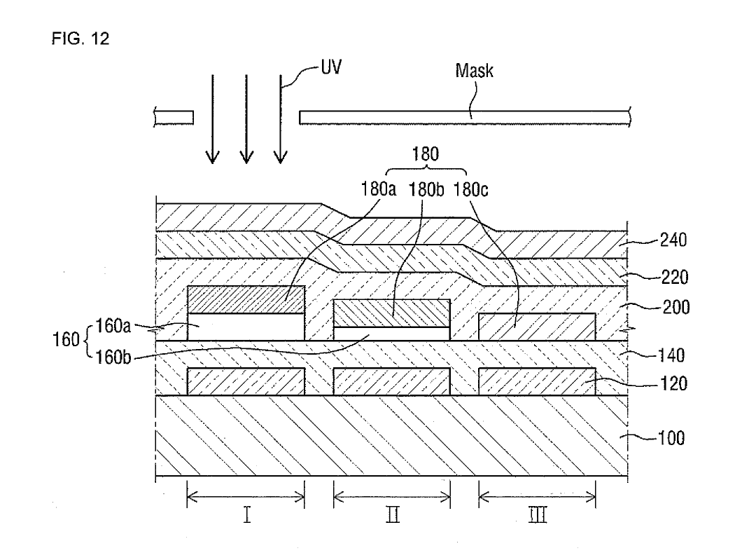

A method of manufacturing an organic light-emitting display device according to another embodiment of the present invention will now be described with reference to FIGS. 12 through 17. FIGS. 12 through 17 are cross-sectional views illustrating a method of manufacturing the organic light-emitting display device of FIG. 11. For simplicity, elements substantially identical to those of FIG. 11 are indicated by like reference numerals, and thus a redundant description thereof will not be provided again.

Referring to FIG. 12, a surface of a capping layer 240 disposed on a first area I may be irradiated with light as in the process of FIG. 4. At this time, the surface of the capping layer 240 disposed on the first area I may become hydrophilic.

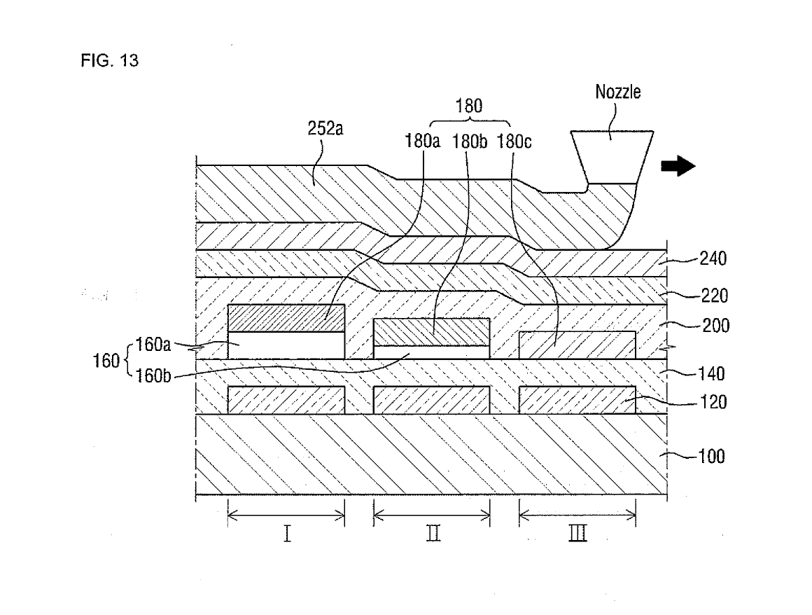

Referring to FIG. 13, a first polymer solution 252a may be spread over the capping layer 240. Here, a thickness to which the first polymer solution 252a is spread may be substantially equal to a thickness t3 of a first refractive pattern 262a which will be formed later. The first polymer solution 252a spread as described above may agglomerate only on the surface of the capping layer 240 disposed on the first area I.

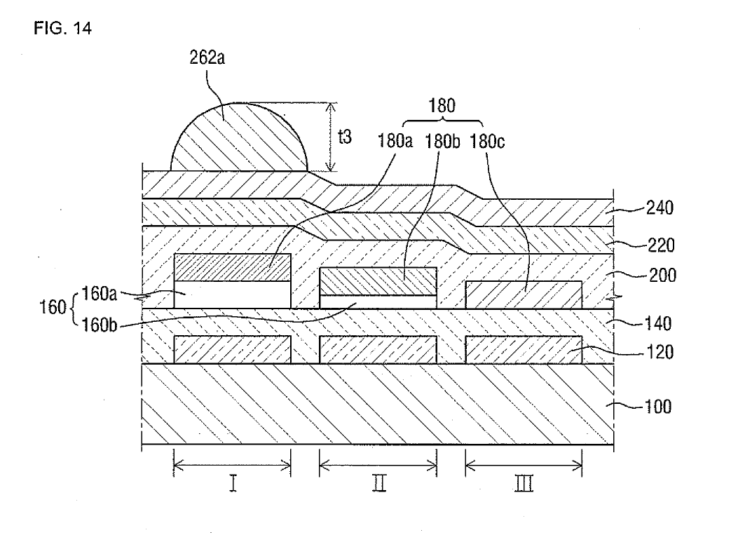

Referring to FIG. 14, the first polymer solution 252a existing on a hydrophobic surface of the capping layer 240 may be removed, and the first polymer solution 252a existing on the hydrophilic surface of the capping layer 240 may be left unremoved. Then, a solvent of the remaining first polymer solution 252a may be evaporated to form the first refractive pattern 262a. Here, a surface of the first refractive pattern 262a may become hydrophobic.

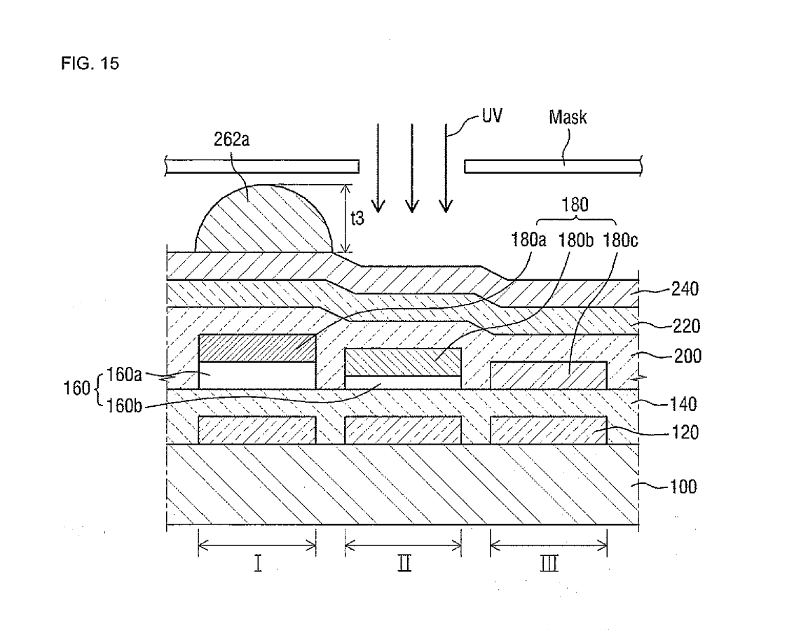

Referring to FIG. 15, a surface of the capping layer 240 disposed on a second area II may be irradiated with light. At this time, the surface of the capping layer 240 disposed on the second area II may become hydrophilic.

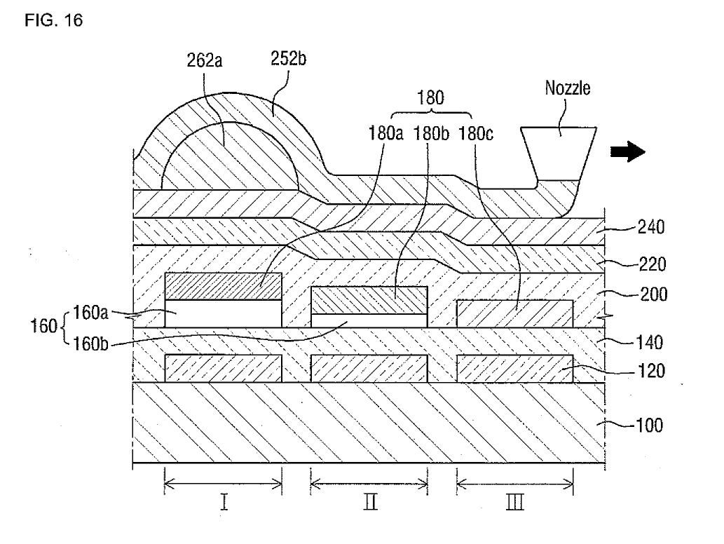

Referring to FIG. 16, a second polymer solution 252b may be spread over the capping layer 240 and the first refractive pattern 262a. Here, a thickness to which the second polymer solution 252b is spread may be substantially equal to a thickness t4 of a second refractive pattern 262b which will be formed later. The second polymer solution 252b spread as described above may agglomerate only on the surface of the capping layer 240 disposed on the second area II.

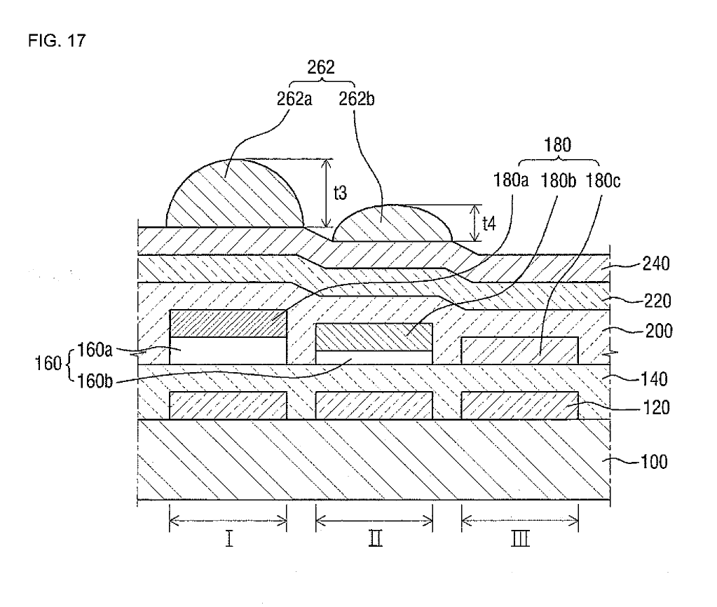

Referring to FIG. 17, the second polymer solution 252b existing on the hydrophobic surface of the capping layer 240 may be removed, and the second polymer solution 252b existing on the hydrophilic surface of the capping layer 240 may be left unremoved. Then, a solvent of the remaining second polymer solution 252b may be evaporated to form the second refractive pattern 262b. Here, a surface of the second refractive pattern 262b may become hydrophobic.

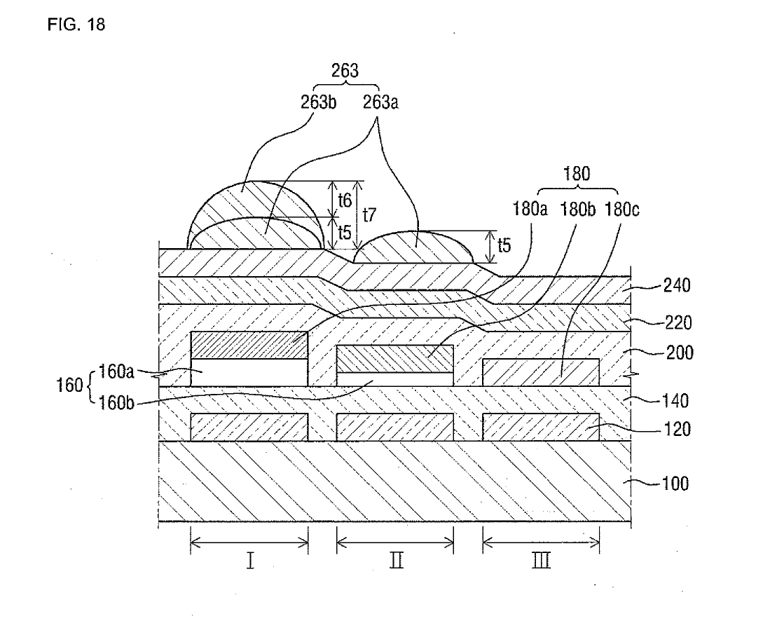

An organic light-emitting display device according to another embodiment of the present invention will now be described with reference to FIG. 18. FIG. 18 is a cross-sectional view of an organic light-emitting display device according to another embodiment of the present invention. For simplicity, elements substantially identical to those of FIG. 1 are indicated by like reference numerals, and thus a redundant description thereof will not be provided again.

Referring to FIG. 18, in one embodiment, at least one of refractive patterns 263 of the organic light-emitting display device according to the current embodiment has a multilayer structure. In the example embodiment of FIG. 18, a first refractive pattern 263a having a thickness of t5 is formed on a capping layer 240 disposed on each of a first area I and a second area II. A second refractive pattern 263b having a thickness of t6 is formed on the first refractive pattern 263a disposed on the first area I. That is, a refractive pattern 263 having a thickness of t7 is formed on the capping layer 240 disposed on the first area I. Here, t7 is greater than t5.

In the organic light-emitting display device according to the current embodiment, the lateral visibility levels of red light, green light and blue light can be adjusted to be equal.

In addition, it is possible to improve the luminance of light generated from each of a first emitting layer 180a and a second emitting layer 180b. Furthermore, a second resonance distance adjusting layer 160b as well as a first resonance distance adjusting layer 160a can be omitted.

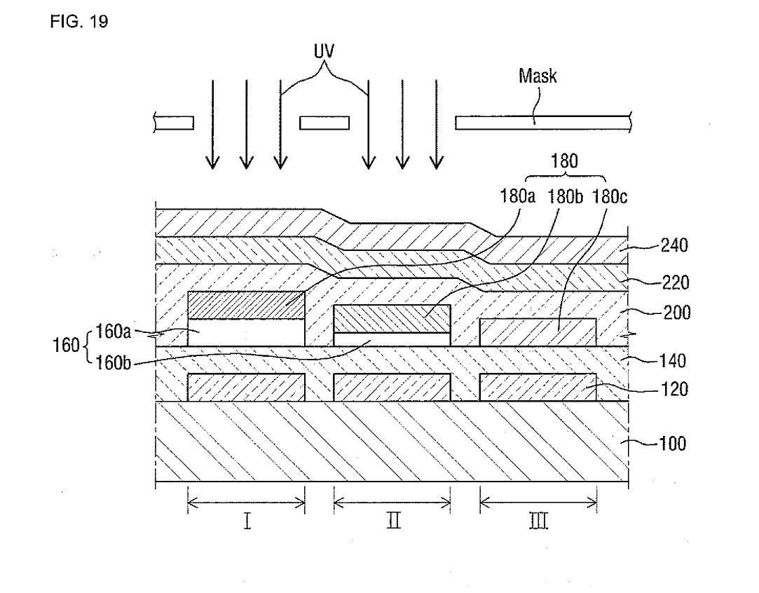

A method of manufacturing an organic light-emitting display device according to another embodiment of the present invention will now be described with reference to FIGS. 19 through 24. FIGS. 19 through 24 are cross-sectional views illustrating a method of manufacturing the organic light-emitting display device of FIG. 18. For simplicity, elements substantially identical to those of FIG. 18 are indicated by like reference numerals, and thus a redundant description thereof will not be provided again.

Referring to FIG. 19, a surface of a capping layer 240 disposed on a first area I and a surface of the capping layer 240 disposed on a second area II may be irradiated with light. Here, the surface of the capping layer 240 disposed on the first area I and the surface of the capping layer 240 disposed on the second area II may become hydrophilic.

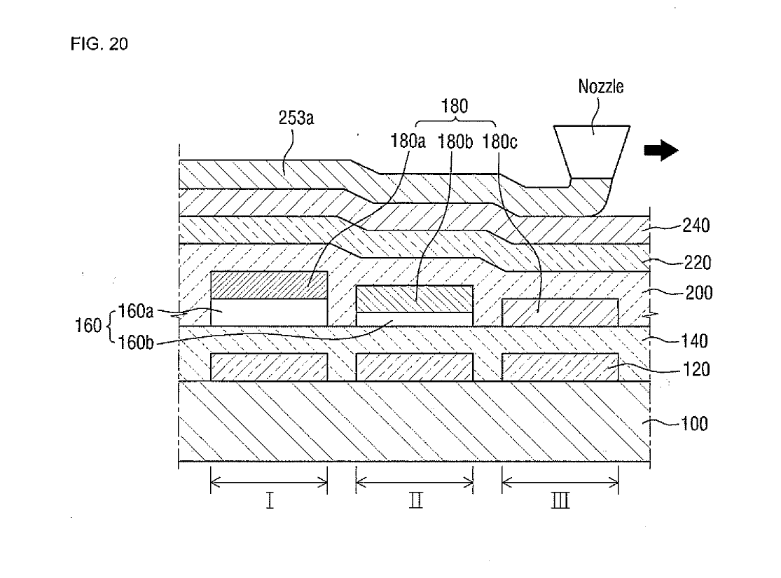

Referring to FIG. 20, a first polymer solution 253a may be spread over the capping layer 240. Here, a thickness to which the first polymer solution 253a is spread may be substantially equal to a thickness t5 of a first refractive pattern 263a which will be formed later. The first polymer solution 253a spread as described above may agglomerate only on the surface of the capping layer 240 disposed on the first area I and on the surface of the capping layer 240 disposed on the second area II.

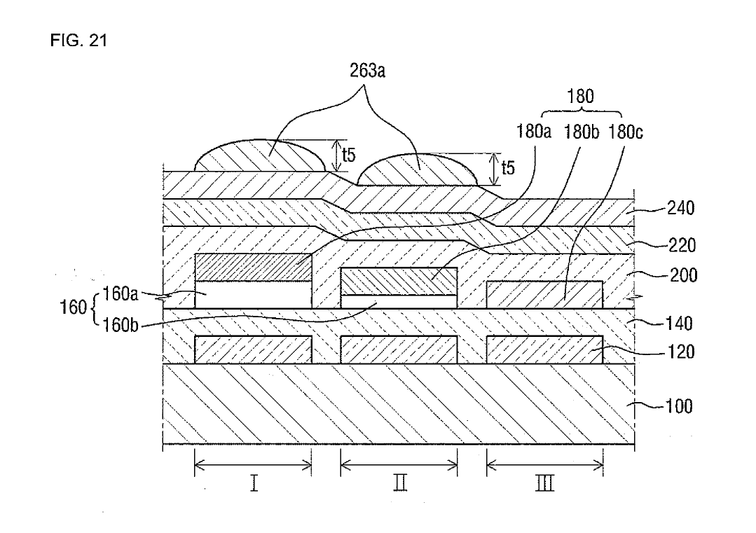

Referring to FIG. 21, the first polymer solution 253a existing on a hydrophobic surface of the capping layer 240 may be removed, and the first polymer solution 253a existing on the hydrophilic surfaces of the capping layer 240 may be left unremoved. Then, a solvent of the remaining first polymer solution 253a may be evaporated to form the first refractive pattern 263a. Here, a surface of the first refractive pattern 263a may become hydrophobic.

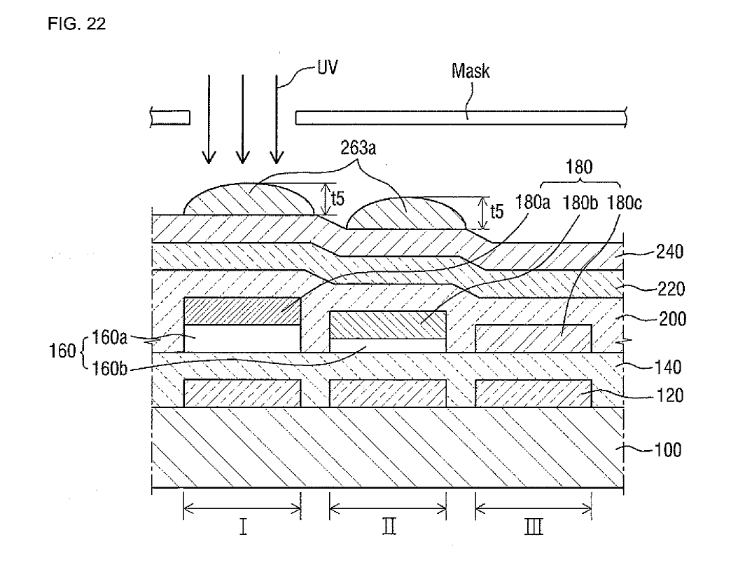

Referring to FIG. 22, the surface of the first refractive pattern 263a disposed on the first area I may be irradiated with light. Here, the surface of the first refractive pattern 263a disposed on the first area I may become hydrophilic.

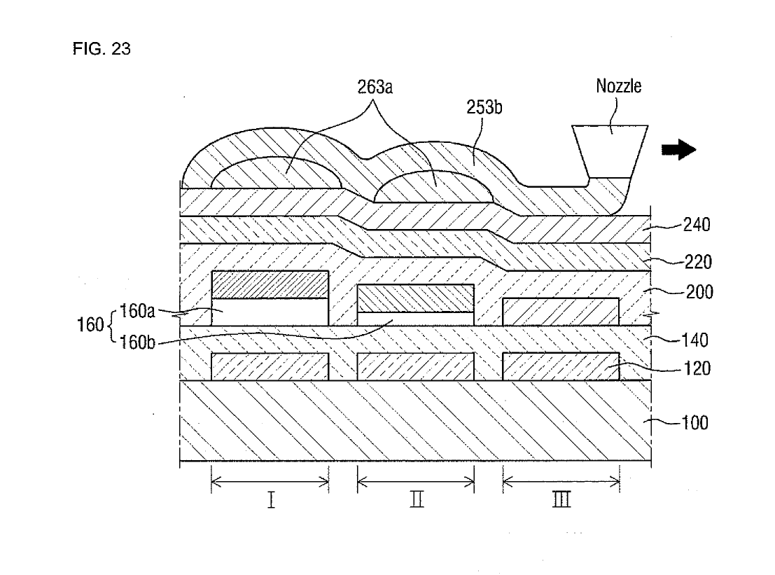

Referring to FIG. 23, a second polymer solution 253b may be spread over the capping layer 240 and the first refractive pattern 263a. Here, a thickness to which the second polymer solution 253b is spread may be substantially equal to a thickness t6 of a second refractive pattern 263b which will be formed later. The second polymer solution 253b spread as described above may agglomerate only on the surface of the first refractive pattern 263a disposed on the first area I.

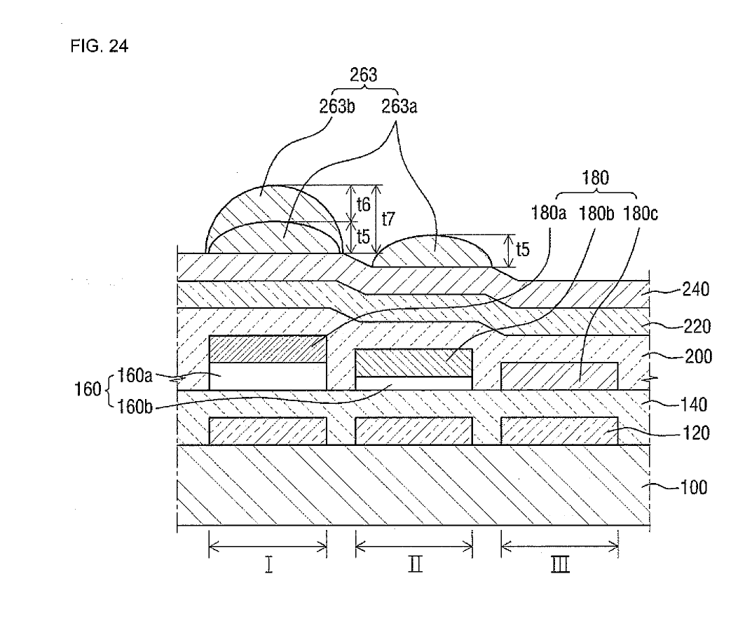

Referring to FIG. 24, the second polymer solution 253b existing on the hydrophobic surface of the capping layer 240 and the first refractive pattern 263a may be removed, and the second polymer solution 253b existing on the hydrophilic surface of the capping layer 240 and the first refractive pattern 263a may be left unremoved. Then, a solvent of the remaining second polymer solution 253b may be evaporated to form the second refractive pattern 263b. Here, a surface of the second refractive pattern 263b may become hydrophobic.

Embodiments of the present invention provide at least one of the following enhancements.

That is, it is possible to improve the luminance and lateral visibility of light emitted from an emitting layer according to the color of the light.

However, the effects of the present invention are not restricted to the one set forth herein. The above and other effects of the present invention will become more apparent to one of ordinary skill in the art to which the present invention pertains by referencing the claims and equivalents thereof.

While the present invention has been particularly shown and described with reference to example embodiments thereof, it will be understood by those of ordinary skill in the art that various changes in form and details may be made therein without departing from the spirit and scope of the present invention as defined by the following claims and equivalents thereof. It is therefore desired that the present embodiments be considered in all respects as illustrative and not restrictive, reference being made to the appended claims and equivalents thereof rather than the foregoing description to indicate the scope of the invention.

What is claimed is:

1. An organic light-emitting display device comprising:
a substrate having a first area and a second area;
a first electrode on each of the first area and the second area of the substrate;
a plurality of emitting layers on the first electrode and comprising a first emitting layer on the first area and a second emitting layer on the second area;
a second electrode on the plurality of emitting layers;
a capping layer on the second electrode; and
a refractive pattern on the capping layer,
wherein the refractive pattern is on at least one of the first area and the second area.

2. The display device of claim 1, wherein a refractive index of the refractive pattern and a refractive index of the capping layer are different.

3. The display device of claim 2, wherein the refractive index of the refractive pattern is higher than the refractive index of the capping layer.

4. The display device of claim 1, wherein the refractive pattern comprises:
a first refractive pattern on the first area; and
a second refractive pattern on the second area,
wherein a thickness of the first refractive pattern and a thickness of the second refractive pattern are different.

5. The display device of claim 1, wherein the refractive pattern comprises:
a first refractive pattern on the first area; and
a second refractive pattern on the second area,
wherein a refractive index of the first refractive pattern and a refractive index of the second refractive pattern are different.

6. The display device of claim 1, wherein the refractive pattern comprises:
a first refractive pattern on each of the first area and the second area; and
a second refractive pattern on the first refractive pattern and on the first area.

7. The display device of claim 6, wherein the combination of the first refractive pattern and the second refractive pattern as the portion of the refractive pattern on the first area is thicker than the first refractive pattern as the portion of the refractive pattern on the second area.

8. The display device of claim 1, further comprising a plurality of resonance distance adjusting layers between the first electrode and the emitting layers, wherein the plurality of resonance distance adjusting layers comprise:
a first resonance distance adjusting layer on the first area; and
a second resonance distance adjusting layer on the second area,
wherein the first resonance distance adjusting layer is thicker than the second resonance distance adjusting layer.

9. The display device of claim 1, wherein the substrate further comprises a third area, wherein the first electrode is also on the third area of the substrate, and the plurality of emitting layers further comprise a third emitting layer on the third area.

10. The display device of claim 9, wherein the refractive pattern is not on the third area.

11. The display device of claim 9, wherein the first emitting layer is configured to emit red light, the second emitting layer is configured to emit green light, and the third emitting layer is configured to emit blue light.

12. The display device of claim 1, wherein the refractive pattern has a convex shape.

13. The display device of claim 12, wherein the refractive pattern on any one of the first area and the second area comprises a plurality of convex portions.

14. An organic light-emitting display device comprising:
a substrate having a first area and a second area;
a first electrode on each of the first area and the second area of the substrate;
a plurality of emitting layers on the first electrode and comprising a first emitting layer on the first area and a second emitting layer on the second area;
a second electrode on the plurality of emitting layers;
a capping layer on the second electrode; and
a refractive pattern on the capping layer,
wherein the refractive pattern has a convex shape.

15. The display device of claim 14, wherein the refractive pattern is on at least one of the first area and the second area.

16. The display device of claim 15, wherein the substrate further comprises a third area, wherein the first electrode is also on the third area of the substrate, the plurality of emitting layers further comprise a third emitting layer on the third area, and the refractive pattern is not on the third area.

17. A method of manufacturing an organic light-emitting display device, the method comprising:
forming a first electrode on each of a first area, a second area and a third area of a substrate;
forming a first emitting layer, a second emitting layer and a third emitting layer on the first electrode on the first area, the first electrode on the second area and the first electrode on the third area, respectively;
forming a second electrode on the first emitting layer, the second emitting layer and the third emitting layer;
forming a capping layer on the second electrode; and
forming a refractive pattern on at least one of the capping layer on the first area and the capping layer on the second area.

18. The method of claim 17, wherein the forming of the refractive pattern comprises:
irradiating light to at least one of the capping layer on the first area and the capping layer on the second area; and
spreading a polymer solution over a whole surface of the capping layer.

19. The method of claim 18, wherein the irradiating of light comprises:
placing a plurality of openings of a mask over any one of the capping layer on the first area and the capping layer on the second area; and
irradiating light onto the capping layer through the openings.

20. The method of claim 18, wherein the forming of the refractive pattern comprises forming a first refractive pattern and a second refractive pattern on the capping layer on the first area and the capping layer on the second area respectively by performing the irradiating of the light and the spreading of the polymer solution at least twice, wherein a thickness of the first refractive pattern and a thickness of the second refractive pattern are different.
